(19) United States
(12) Patent Application Publication
(10) Pub. No.: US 2006/0286815 A1
(43) Pub. Date: Dec. 21, 2006

(54) Interlayer insulating film formation method and film structure of interlayer insulating film

(76) Inventor: Nobuo Aoi, Hyogo (JP)

Correspondence Address: MCDERMOTT WILL & EMERY LLP, 600 13TH STREET, N.W., WASHINGTON, DC, 20005-3096, US

(21) Appl. No.: 11/453,871

(22) Filed: Jun. 16, 2006

(30) Foreign Application Priority Data
Jun. 16, 2005 (JP) 2005-176877

(51) Int. Cl. H01L 23/58; H01L 21/31

(52) U.S. Cl. 438/790; 257/632

(57) ABSTRACT

An interlayer insulating film formation method for forming an interlayer insulating film on a substrate includes the step of forming the interlayer insulating film through plasma CVD by using an organic silicon compound including no oxygen atom and an organic silicon compound including an oxygen atom as materials.

### CROSS-REFERENCE TO RELATED APPLICATIONS

This application claims priority under 35 U.S.C. § 119 on Patent Application No. 2005-176877 filed in Japan on Jun. 16, 2005, the entire contents of which are hereby incorporated by reference.

### BACKGROUND OF THE INVENTION

The present invention relates to a method for forming an interlayer insulating film with a low dielectric constant, and more particularly, it relates to a method for forming a low dielectric constant interlayer insulating film having a function to prevent diffusion of copper ions and a film structure of the interlayer insulating film.

As an insulating film to be used as a copper diffusion barrier film in very large scale integration (VLSI) having copper interconnects, a SiN film, a SiON film, a SiC film, a SiCO film or the like is conventionally known, and all of these insulating films have a high dielectric constant of 4 or more. Therefore, even when a low dielectric constant film is used as an interlayer insulating film in a multilayered interconnect structure, the influence of the dielectric constant of the aforementioned insulating film used as the copper diffusion barrier film is dominant. Accordingly, the effect to reduce the dielectric constant by using the interlayer insulating film made of the low dielectric constant film in the multilayered interconnect structure is cancelled by the dielectric constant of the insulating film used as the copper diffusion barrier film, and hence, a sufficiently low value has not been realized as the effective dielectric constant of the whole multilayered interconnect structure.

In order to cope with such a problem, it is necessary to reduce the dielectric constant of an insulating film used as a copper diffusion barrier film or provide an interlayer insulating film made of a low dielectric constant film with a function as a copper diffusion barrier film.

As a conventional technique for reducing the dielectric constant of a copper diffusion barrier film, a method for forming a SiCN film through plasma CVD using trimethyl vinylsilane has been reported, and this SiCN film has a dielectric constant of 4. Alternatively, a method for forming a low dielectric constant interlayer insulating film having a function as a copper diffusion barrier film through plasma CVD using divinylsiloxane bis-benzocyclobutene has been reported, and this low dielectric constant film has a dielectric constant of approximately 2.7 (see, for example, Japanese Patent No. 3190886 and Jpn. J. Appl. Phys. Vol. 42 (2003) pp. L910-L913).

### SUMMARY OF THE INVENTION

The SiCN film formed as a copper diffusion barrier film by using trimethyl vinylsilane has a dielectric constant of 4, and the dielectric constant is disadvantageously high.

Also, the low dielectric constant interlayer insulating film having the function as a copper diffusion barrier film formed by using divinylsiloxane bis-benzocyclobutene is disadvantageously expensive because divinylsiloxane bis-benzocyclobutene used as the material has a complicated chemical structure.

Furthermore, in order to perform deposition by the plasma CVD using divinylsiloxane bis-benzocyclobutene, it is necessary to vaporize the material through a thermal treatment, and a temperature of 150° C. or more is necessary for the vaporization. The divinylsiloxane bis-benzocyclobutene used as the material is easily polymerized through a thermal treatment at, for example, 150° C. or more, namely, easily thermally polymerized. Therefore, the material is polymerized in a carburetor and a solid or a liquid is produced within the carburetor so as to clog a pipe, resulting in lowering the working efficiency of a CVD system used for the deposition.

Moreover, the divinylsiloxane bis-benzocyclobutene used as the material is a thermally polymerizable material and is low at thermal stability. Furthermore, since the material includes a bifunctional monomer, a polymerized film formed by the plasma CVD using the monomer is basically constructed from a straight-chain polymer. Therefore, the interlayer insulating film formed by the plasma CVD using the divinylsiloxane bis-benzocyclobutene as the material is poor at mechanical strength (elasticity modulus and hardness), and hence, it is difficult to integrate as an interlayer insulating film of a multilayered interconnect structure.

Furthermore, the interlayer insulating film formed by the plasma CVD using the divinylsiloxane bis-benzocyclobutene as the material is insufficient in the content of an organic component, and since the content of the organic component depends upon an organic component included in the divinylsiloxane bis-benzocyclobutene, the controllable range of the content of the organic component in the interlayer insulating film to be formed is restricted.

Also, since the interlayer insulating film formed by the plasma CVD using the divinylsiloxane bis-benzocyclobutene as the material is formed through plasma polymerization from a disiloxane derivative, its organic component is partially decomposed by the plasma, and hence, the organic component taken into the interlayer insulating film to be formed is reduced. Therefore, there is a limit in reducing the content of a siloxane component in the interlayer insulating film to be formed, namely, in increasing the content of the organic component. Accordingly, the interlayer insulating film formed by using the plasma CVD system with the divinylsiloxane bis-benzocyclobutene used as the material cannot sufficiently prevent diffusion of copper ions for the following reason: Since a physical distance between siloxane sites depends upon the content of the organic component, when the content of the organic component is small, the physical distance between siloxane sites is smaller than a hopping distance of a copper ion, and therefore, the function to prevent the diffusion of copper ions is insufficient. In other words, as the physical distance between siloxane sites is larger, the potential energy, and the height of a barrier in the end, necessary for moving a copper ion is larger, and hence, the function to prevent the diffusion of copper ions is higher. However, in the case where the physical distance between siloxane sites is too large, a distance at which a copper ion can move without being trapped by a siloxane site is relatively longer, and therefore, the thickness of the interlayer insulating film necessary for efficiently trapping copper ions is disadvantageously large.

Furthermore, since the interlayer insulating film formed by the plasma CVD using the divinylsiloxane bis-benzocyclobutene as the material is formed by polymerizing the organic component, there is a limit in improving the mechanical strength of the interlayer insulating film. This is because the bond strength between carbon in a polymerized polymer network made of the organic component is weaker than the bond strength of a siloxane bond.

In consideration of the aforementioned conventional problems and disadvantages, an object of the invention is providing an interlayer insulating film that is good at a copper ion diffusion preventing function, thermal stability and mechanical strength and is formed by an inexpensive method in which the working efficiency of a fabrication system is not lowered.

As a method for overcoming the above-described conventional problem, the following methods have been proposed: An interlayer insulating film that has a low dielectric constant (of 2.5), is thermally stable and has a function to prevent diffusion of copper ions is formed by an inexpensive method in which the working efficiency of a fabrication system is not lowered by using a disiloxane derivative having a simple chemical structure and having a substituent with two or more functional groups and with no thermal polymerization property; and an interlayer insulating film that is good at mechanical strength and has a function to prevent diffusion of copper ions is formed through three-dimensional polymerization using a disiloxane derivative having three or more functional groups.

In the interlayer insulating film having the copper ion diffusion preventing function formed by the plasma CVD using the disiloxane derivative having a simple chemical structure and having a substituent with two or more functional groups and with no thermal polymerization property, a siloxane site surrounded with organic sites functions as a site for trapping a copper ion. Accordingly, a structure in which a siloxane site is three-dimensionally surrounded with organic sites is the essential condition for providing the copper ion diffusion preventing function.

At the early stage of forming the interlayer insulating film by the plasma CVD, however, the structure in which the siloxane site working as the site for trapping a copper ion is three-dimensionally surrounded with organic sites is not completed yet, and hence, copper ions are easily diffused from a copper interconnect formed below the interlayer insulating film by the heat applied in the deposition process. Accordingly, even in the interlayer insulating film having the copper ion diffusion preventing function, the diffusion of copper ions cannot be sufficiently prevented at the early stage of the deposition, and hence, the reliability as the copper ion diffusion barrier film is disadvantageously lowered.

In consideration of the aforementioned conventional disadvantage, an object of the invention is preventing diffusion of copper ions from a copper interconnect at the early stage of deposition of an interlayer insulating film having the copper ion diffusion preventing function.

In order to achieve the objects, according to a first aspect of the invention, the interlayer insulating film formation method for forming an interlayer insulating film on a substrate includes the step of forming the interlayer insulating film through plasma CVD by using an organic silicon compound including no oxygen atom and an organic silicon compound including an oxygen atom as materials.

According to a second aspect of the invention, the interlayer insulating film formation method for forming an interlayer insulating film on a substrate includes the step of forming the interlayer insulating film through plasma CVD by using an organic compound including no oxygen atom and an organic silicon compound including an oxygen atom as materials.

According to a third aspect of the invention, the interlayer insulating film formation method for forming an interlayer insulating film on a substrate includes the step of forming the interlayer insulating film through plasma CVD by using an organic silicon compound including no oxygen atom and an organic compound including an oxygen atom.

In the interlayer insulating film formation method according to any of the first through third aspects of the invention, an interlayer insulating film that is good at the copper ion diffusion preventing function, the thermal stability and the mechanical strength is obtained by an inexpensive method in which the working efficiency of a fabrication system is not lowered. Furthermore, in the interlayer insulating film formation method according to the second or third aspect of the invention, the content of an organic component in the interlayer insulating film can be increased, and hence, the interlayer insulating film can attain a better copper diffusion preventing function.

In the interlayer insulating film formation method of any of the first through third aspects, when a gas of nitrogen or a gas of ammonia is used as an additive gas in the step of forming the interlayer insulating film, a bond of silicon and nitrogen (a Si-N bond) or a bond of carbon and nitrogen (a C-N bond) is formed in the interlayer insulating film, and hence, the copper ion diffusion preventing function of the interlayer insulating film can be improved.

In the interlayer insulating film formation method of the first or third aspect, the organic silicon compound including no oxygen atom can be monomethylsilane, dimethylsilane, trimethylsilane, tetramethylsilane or hexamethyldisilane.

In the interlayer insulating film formation method of the first or second aspect, an organic group bonded to a silicon atom included in the organic silicon compound including an oxygen atom is preferably a methyl group, an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group or a derivative of a phenyl group.

In the interlayer insulating film formation method of the second aspect, the organic compound including no oxygen atom is preferably saturated carbon hydride or unsaturated carbon hydride. In this case, the saturated carbon hydride is preferably methane, ethane, propane, butane, pentane, hexane, heptane, octane, nonane, decane or an isomer of any of them, and the unsaturated carbon hydride preferably includes one or more and three or less double bonds of carbon atoms.

In the interlayer insulating film formation method of the third aspect, the organic compound including an oxygen atom is preferably ether, ester, alcohol, ketone or a carboxylic acid derivative.

The film structure of an interlayer insulating film according to another aspect of the invention includes an organic polymer including carbon atoms and hydrogen atoms as principal components, and a first silicon atom bonded to a part the carbon atoms and not bonded to an oxygen atom and a second silicon atom bonded to a part of the carbon atoms and bonded to an oxygen atom are mixedly present in the organic polymer.

According to the film structure of an interlayer insulating film of this aspect of the invention, an interlayer insulating film good at the copper diffusion preventing function, the thermal stability and the mechanical strength can be realized.

In the film structure of an interlayer insulating film, a ratio of the number of the carbon atoms to the number of the first silicon atom and the second silicon atom included in the interlayer insulating film is preferably 1.5 or more.

In this manner, according to the present invention, an interlayer insulating film good at the copper diffusion preventing function, the thermal stability and the mechanical strength is provided by an inexpensive method in which the working efficiency of a fabrication system is not lowered.

### BRIEF DESCRIPTION OF THE DRAWINGS

FIG. 1A is a diagram for schematically showing a main chain, in which a siloxane site and an organic molecule site are alternately bonded, of an interlayer insulating film obtained by an interlayer insulating film formation method of the invention and FIG. 1B is a diagram for schematically showing a main chain in which siloxane sites are bonded to each other;

FIG. 2 is a graph for showing the relationship between a drift rate of a copper ion and a temperature obtained in the interlayer insulating film formed by the interlayer insulating film formation method of the invention;

FIG. 3 is a schematic diagram for showing the architecture of a CVD system used in Embodiment 1;

FIG. 4 is a diagram for showing an example of chemical structural formulas of CVD materials used in an interlayer insulating film formation method of Embodiment 1;

FIG. 5 is a schematic diagram for showing the architecture of a CVD system used in Embodiment 2;

FIG. 6 is a diagram for showing an example of chemical structural formulas of CVD materials used in an interlayer insulating film formation method of Embodiment 2;

FIG. 7 is a schematic diagram for showing the architecture of a CVD system used in Embodiment 3; and

FIG. 8 is a diagram for showing an example of chemical structural formulas of CVD materials used in an interlayer insulating film formation method of Embodiment 3.

### DETAILED DESCRIPTION OF THE INVENTION

Before describing preferred embodiments of the invention, an interlayer insulating film formation method employing plasma CVD of this invention attained as a result of various examinations made by the present inventor for achieving the aforementioned objects will be described.

First, in an interlayer insulating film formation method (1) employing plasma CVD of this invention, an organic silicon compound including no oxygen atom and an organic silicon compound including an oxygen atom are plasma copolymerized through the plasma CVD. Thus, a siloxane bond can be introduced without using an oxidizer, and since an organic group of the organic silicon is not oxidized in this manner, the content of siloxane can be reduced and the content of an organic component can be increased. Also, the bond energy between a silicon atom and a carbon atom (that is, 414 kJ/mol) is larger than the bond energy between carbon atoms (that is, 370 kJ/mol), and a polymerization network of a silicon atom and a carbon atom is introduced into an interlayer insulating film thus formed, and hence, the mechanical strength of the interlayer insulating film can be improved. Accordingly, a low dielectric constant interlayer insulating film good at a copper ion diffusion preventing function, thermal stability and mechanical strength can be realized.

Alternatively, in an interlayer insulating film formation method (2) employing the plasma CVD of this invention, an organic compound including no oxygen atom and an organic silicon compound including an oxygen atom are plasma copolymerized through the plasma CVD. Thus, a siloxane bond can be introduced without using an oxidizer, and since an organic group of the organic silicon is not oxidized, the content of siloxane can be reduced and the content of an organic component can be increased. Also, since a polymerization network of a silicon atom and a carbon atom is introduced into an interlayer insulating film thus formed, the mechanical strength of the interlayer insulating film can be improved. Accordingly, a low dielectric constant interlayer insulating film good at the copper ion diffusion preventing function, the thermal stability and the mechanical strength can be realized. In this case, the interlayer insulating film can attain a higher copper ion diffusion preventing function by increasing the content of the organic component.

Alternatively, in an interlayer insulating film formation method (3) employing the plasma CVD of this invention, an organic silicon compound including no oxygen atom and an organic compound including an oxygen atom are plasma copolymerized through the plasma CVD. Thus, a siloxane bond can be introduced without using an oxidizer, and since an organic group of the organic silicon is not oxidized, the content of siloxane can be reduced and the content of an organic component can be increased. Also, since a polymerization network of a silicon atom and a carbon atom is introduced into an interlayer insulating film thus formed, the mechanical strength of the interlayer insulating film can be improved. Accordingly, a low dielectric constant interlayer insulating film good at the copper ion diffusion preventing function, the thermal stability and the mechanical strength can be realized. In this case, the interlayer insulating film can attain a higher copper ion diffusion preventing function by increasing the content of the organic component.

In the film structure of the interlayer insulating film obtained by any of these interlayer insulating film formation methods (1) through (3), a first silicon atom bonded to a part of carbon atoms but not bonded to an oxygen atom and a second silicon atom bonded to a part of carbon atoms and bonded to an oxygen atom are mixedly present in an organic polymer including carbon atoms and hydrogen atoms as principal components. In this case, the ratio of the number of carbon atoms to the number of the first silicon atom and the second silicon atom included in the film is 1.5 or more. The interlayer insulating film having such a film structure is good at the copper ion diffusion preventing function, the thermal stability and the mechanical strength.

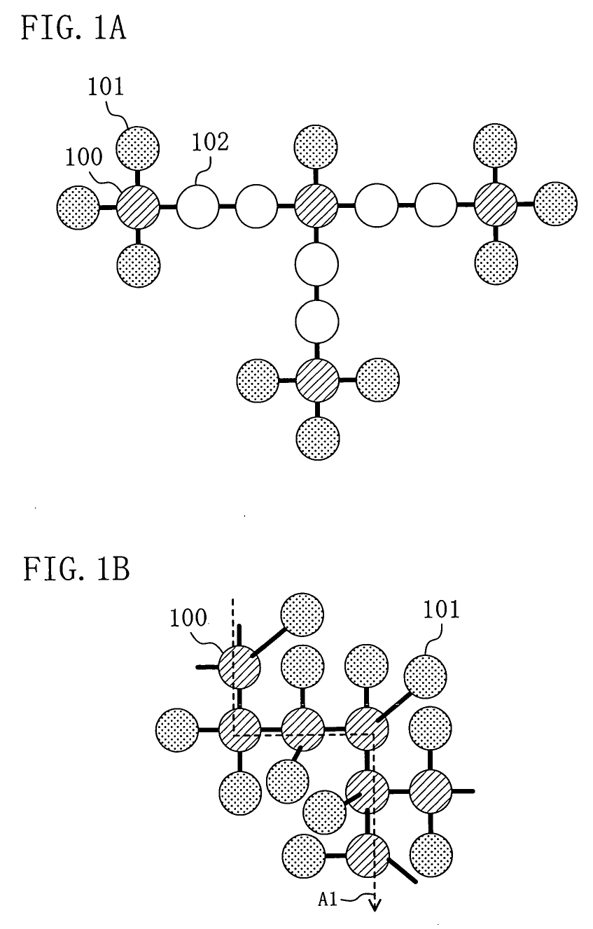

Now, the mechanism for preventing copper diffusion of the low dielectric constant interlayer insulating film formed through the plasma CVD according to the invention will be described with reference to FIGS. 1A and 1B. FIG. 1A is a diagram for schematically showing the principal portion of the film structure of the interlayer insulting film formed through the plasma CVD of this invention and FIG. 1B is a schematic diagram of the principal portion of the film structure of a conventional interlayer insulating film. In each of FIGS. 1A and 1B, a siloxane site 100, an organic molecule site 101 not included in a main chain and an organic molecule site 102 included in the main chain are respectively schematically shown.

First, as shown in FIG. 1A, the interlayer insulating film of this invention has a film structure having a main chain in which the siloxane site 100 and the organic molecule site 102 are alternately bonded. Specifically, the diffusion of copper ions is suppressed in a bond portion between the siloxane site 100 and the organic molecule site 102 included in the main chain, and therefore, the copper ions are minimally diffused along the main chain in this film structure. In other words, since a copper ion minimally passes through the bond portion between the siloxane site 100 and the organic molecule site 102 included in the main chain, the copper ion is easily trapped by the siloxane site. This is because the potential energy, and the barrier height in the end, required for a copper ion to move from a portion in the vicinity of an oxygen atom of the siloxane site 100 to a portion in the vicinity of a carbon atom of the organic molecule site 102 included in the main chain are very large.

On the other hand, in the conventional interlayer insulating film, since the siloxane sites 100 are bonded to form a main chain as shown in FIG. 1B, a copper ion is easily diffused along the main chain composed of siloxane. For example, a copper ion moves along an arrow A1. This is because the potential energy, and the barrier height in the end, necessary for a copper ion to move from a portion in the vicinity of an oxygen atom to a portion in the vicinity of a silicon atom in the siloxane bond are very small.

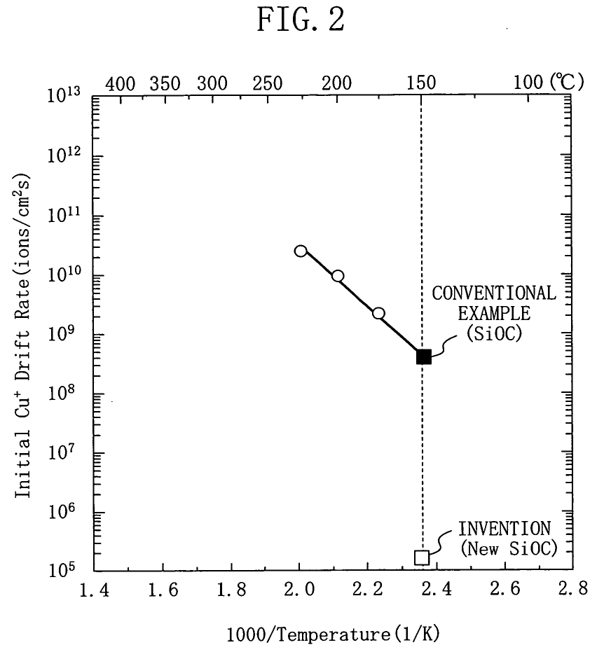

Furthermore, FIG. 2 shows the relationship between a drift rate (ions/cm²s) of a copper ion and a temperature (1/K) obtained in the interlayer insulating film formed by the interlayer insulating film formation method (1) employing the plasma CVD of this invention.

As is obvious from FIG. 2, the drift rate obtained in the interlayer insulating film of this invention (shown as “New SiOC” in FIG. 2) is much lower than the drift rate obtained in the conventional interlayer insulating film (shown as “SiOC” in FIG. 2).

In this manner, the interlayer insulating film formed by the interlayer insulating film formation method employing the plasma CVD of this invention has an excellent copper ion diffusion preventing function.

Now, preferred embodiments for embodying the interlayer insulating film formation methods (1) through (3) employing the plasma CVD of this invention will be described.

### EMBODIMENT 1

An interlayer insulating film formation method according to Embodiment 1 of the invention for embodying the interlayer insulating film formation method (1) employing the plasma CVD of this invention will be described with reference to the accompanying drawings.

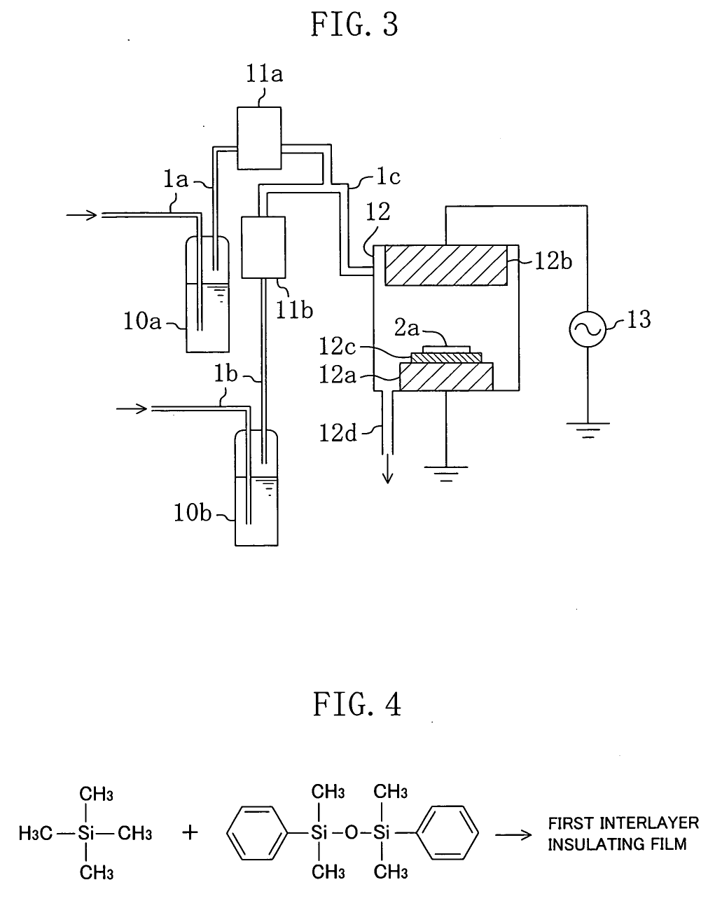

The interlayer insulating film formation method of Embodiment 1 is realized by using a general diode parallel plate cathode coupled plasma enhanced CVD system having an architecture, for example, schematically shown in FIG. 3.

Also, in the interlayer insulating film formation method of Embodiment 1, 1,3-diphenyl-1,1,3,3-tetramethyldisiloxane is used as a first CVD material, that is, the organic silicon compound including an oxygen atom, and tetramethylsilane is used as a second CVD material, that is, the organic silicon compound including no oxygen atom, as shown in FIG. 4. A first interlayer insulating film according to this embodiment can be formed through the plasma CVD using these first and second CVD materials. The method will now be specifically described.

First, 1,3-diphenyl-1,1,3,3-tetramethyldisiloxane used as the first CVD material is filled in a first pressure vessel 10a through a first gas supply pipe la, and tetramethylsilane used as the second CVD material is filled in a second pressure vessel 10b through a second gas supply pipe 1b.

Next, the 1,3-diphenyl-1,1,3,3-tetramethyldisiloxane filled in the first pressure vessel 10a is transported to a first carburetor 11a with pressure of He, the tetramethylsilane filled in the second pressure vessel 10b is transported to a second carburetor 11b with pressure of He, and these materials are vaporized respectively in the first and second carburetors 11a and 11b at 180° C. Then, the vaporized 1,3-diphenyl-1,1,3,3-tetramethyldisiloxane and the vaporized tetramethylsilane are mixed with each other before introducing into a deposition chamber 12, and the resultant mixture is introduced into the deposition chamber 12 through a third gas supply pipe 1c. In the deposition chamber 12, a lower electrode 12a is disposed on the bottom and an upper electrode 12b is disposed above the lower electrode 12a, and a target substrate 2a is placed on a substrate supporting portion 12c provided on the lower electrode 12a. Also, the deposition chamber 12 is provided with an outlet 12d on a side of the lower electrode 12a so that a gas obtained after a reaction or a gas having not sufficiently contributed to the reaction can be successively exhausted.

In this embodiment, with the pressure within the deposition chamber 12 set to 400 Pa and the substrate temperature set to 400° C., while introducing the 1,3-diphenyl-1,1,3,3-tetramethyldisiloxane and the tetramethylsilane into the deposition chamber 12 at flow rates of 10 g/min. and 3 g/min., respectively, power of 0.2 W/cm² is applied to the lower electrode 12a and the upper electrode 12b by a radio frequency (RF) power source 13 for plasma polymerization. During the plasma polymerization, in the 1,3-diphenyl-1,1,3,3-tetramethyldisiloxane used as the first CVD material, for example, a phenyl group is changed into a radical by the plasma, and the phenyl group changed to the radical is copolymerized with the tetramethylsilane. Thus, the first interlayer insulating film is formed.

Herein, the description is made by exemplifying the case where organic groups bonded to silicon of the disiloxane used as the first CVD material are a phenyl group and a methyl group. Since a radical of an alkyl group tends to be unstable, when an alkyl group is used, bond disconnection between silicon and an organic group is easily caused and hence the yield of radical polymerization may be low. However, when at least any group selected from a group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group is used as the organic group bonded to silicon of the disiloxane, a film can be advantageously formed through the radical polymerization because all of these organic groups are more easily changed into radicals than a methyl group. Therefore, a film structure in which siloxane bonds are dispersed in a network of an organic polymer can be thus sufficiently obtained. In particular, a vinyl group, a phenyl group and a derivative of a phenyl group have a it bond capable of easily giving/receiving electrons and hence are effectively used in the plasma enhanced radical polymerization.

Also, in Embodiment 1, when the first interlayer insulating film is formed by using the 1,3-diphenyl-1,1,3,3-tetramethyldisiloxane as the first CVD material, the first interlayer insulating film can be obtained at a deposition rate of 120 nm/min., and its dielectric constant is 2.5. Since the dielectric constant of the above-described conventional interlayer insulating film formed by using the divinylsiloxane bis-benzocyclobutene is 2.7, it is understood that the dielectric constant of the first interlayer insulating film of Embodiment 1 has a better value.

Furthermore, a drift rate of a copper ion obtained in the first interlayer insulating film under conditions of the applied electric field of 0.8 MV/cm and a temperature of 150° C. is 1.0×10⁵ ions/cm²s. Since this drift fate is approximately ⅕ of the drift rate of a copper ion obtained in the conventional interlayer insulating film formed by using the divinylsiloxane bis-benzocyclobutene, it is understood that the first interlayer insulating film of Embodiment 1 has a better copper ion diffusion preventing function than the conventional interlayer insulating film. This seems to be because copper ions are efficiently trapped by the siloxane bonds dispersed in the network of the organic polymer as described above.

Moreover, the elasticity modulus of the first interlayer insulating film of Embodiment 1 measured with a nano indenter is approximately 11 GPa. Accordingly, the first interlayer insulating film has the elasticity modulus approximately twice as large as that of the conventional interlayer insulating film made of an organic low dielectric constant film. Although the 1,3-diphenyl-1,1,3,3-tetramethyldisiloxane is used as the first CVD material in Embodiment 1, the three-dimensional network of the organic polymer can be definitely formed by using disiloxane having, as the organic groups bonded to silicon, three or more groups selected from the group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group. Thus, the elasticity modulus of the first interlayer insulating film can be further improved.

Alternatively, in Embodiment 1, a cyclic siloxane derivative in which any group selected from the group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group is bonded to a silicon atom can be used as the first CVD material instead of the organic disiloxane derivative. When such a cyclic siloxane compound is used as the first CVD material, the three-dimensional network of the organic polymer can be easily formed. As a result, the first interlayer insulating film with high mechanical strength can be definitely formed.

Furthermore, in Embodiment 1, an organic silicon compound in which at least two groups selected from the group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group are bonded to different silicon atoms can be used. Thus, the first interlayer insulating film having a structure in which siloxane bonds are separated from each other by an organic component without being adjacent to each other can be definitely formed.

Moreover, in Embodiment 1, when the deposition is performed through the plasma CVD in an atmosphere including a nitrogen gas or an ammonia gas, a bond of silicon and nitrogen (a Si-N bond) or a bond of carbon and nitrogen (a C-N bond) is formed in the deposited film, and therefore, the copper ion diffusion preventing function of the first interlayer insulating film can be improved.

### EMBODIMENT 2

An interlayer insulating film formation method according to Embodiment 2 of the invention for embodying the interlayer insulating film formation method (2) employing the plasma CVD of this invention will be described with reference to the accompanying drawings.

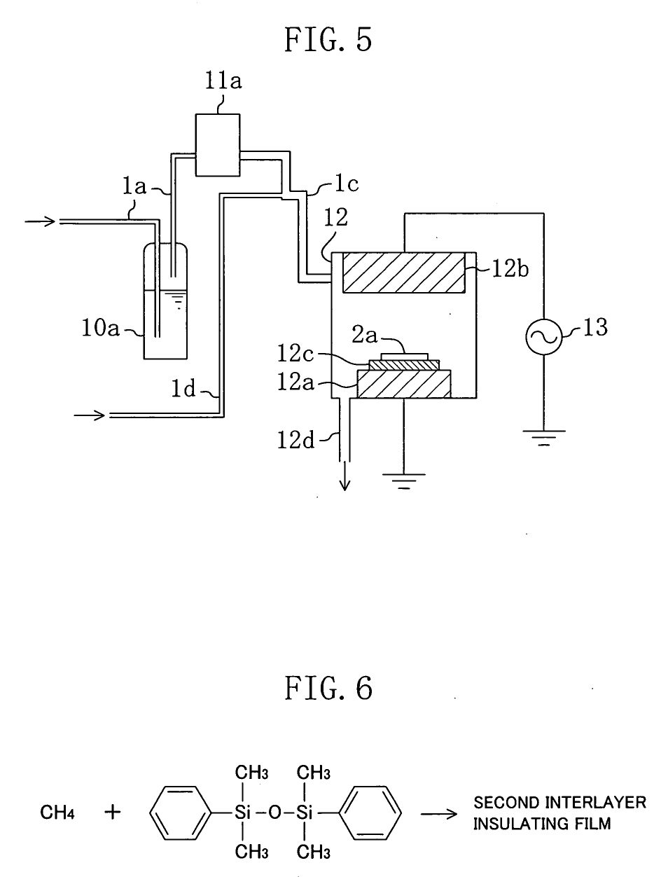

The interlayer insulating film formation method of Embodiment 2 is realized by using a general diode parallel plate cathode coupled plasma enhanced CVD system having an architecture, for example, schematically shown in FIG. 5.

Also, in the interlayer insulating film formation method of Embodiment 2, 1,3-diphenyl-1,1,3,3-tetramethyldisiloxane is used as a first CVD material, that is, the organic silicon compound including an oxygen atom, and methane is used as a second CVD material, that is, the organic compound including no oxygen atom, as shown in FIG. 6. A second interlayer insulating film according to this embodiment can be formed through plasma CVD using these first and second CVD materials. The method will now be specifically described.

First, 1,3-diphenyl-1,1,3,3-tetramethyldisiloxane used as the first CVD material is filled in a first pressure vessel 10a through a first gas supply pipe 1a, and the 1,3-diphenyl-1,1,3,3-tetramethyldisiloxane filled in the first pressure vessel 10a is transported to a first carburetor 11a with pressure of He. Then, the 1,3-diphenyl-1,1,3,3-tetramethyldisiloxane is vaporized in the first carburetor 11a at 180° C. and the vaporized 1,3-dipehnyl-1,1,3,3-tetramethyldisiloxane is introduced into a deposition chamber 12 through a third gas supply pipe 1c. On the other hand, methane is introduced into the deposition chamber 12 through a second gas supply pipe 1d and the third gas supply pipe 1c. In the deposition chamber 12, a lower electrode 12a is disposed on the bottom and an upper electrode 12b is disposed above the lower electrode 12a, and a target substrate 2a is placed on a substrate supporting portion 12c provided on the lower electrode 12a. Also, the deposition chamber 12 is provided with an outlet 12d on a side of the lower electrode 12a so that a gas obtained after a reaction or a gas having not sufficiently contributed to the reaction can be successively exhausted.

In Embodiment 2, with the pressure within the deposition chamber 12 set to 400 Pa and the substrate temperature set to 400° C., while introducing the 1,3-diphenyl-1,1,3,3-tetramethyldisiloxane and the methane into the deposition chamber 12 at flow rates of 10 g/min. and 500 sccm, respectively, power of 0.2 W/cm² is applied to the lower electrode 12a and the upper electrode 12b by a radio frequency (RF) power source 13 for plasma polymerization. During the plasma polymerization, in the 1,3-diphenyl-1,1,3,3-tetramethyldisiloxane used as the first CVD material, for example, a phenyl group is changed into a radical by the plasma, and the phenyl group changed to the radical is copolymerized with the methane. Thus, the second interlayer insulating film is formed.

Herein, the description is made by exemplifying the case where organic groups bonded to silicon of the disiloxane used as the first CVD material are a phenyl group and a methyl group. Since a radical of an alkyl group tends to be unstable, when an alkyl group is used, bond disconnection between silicon and an organic group is easily caused and hence the yield of radical polymerization may be low. However, when at least any group selected from a group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group is used as the organic group bonded to silicon of the disiloxane, a film can be advantageously formed through the radical polymerization because all of these organic groups are more easily changed into radicals than a methyl group. Therefore, a film structure in which siloxane bonds are dispersed in a network of an organic polymer can be thus sufficiently obtained. In particular, a vinyl group, a phenyl group and a derivative of a phenyl group have a X bond capable of easily giving/receiving electrons and hence are effectively used in the plasma enhanced radical polymerization.

Also, in Embodiment 2, when the second interlayer insulating film is formed by using the 1,3-diphenyl-1,1,3,3-tetramethyldisiloxane as the first CVD material, the second interlayer insulating film can be obtained at a deposition rate of 200 nm/min., and its dielectric constant is 2.4. Since the dielectric constant of the conventional interlayer insulating film formed by using the divinylsiloxane bis-benzocyclobutene is 2.7, it is understood that the dielectric constant of the second interlayer insulating film of Embodiment 2 has a better value.

Furthermore, a drift rate of a copper ion obtained in the second interlayer insulating film under conditions of the applied electric field of 0.8 MV/cm and a temperature of 150° C. is 1.0×10⁵ ions/cm²s. Since this drift fate is approximately ⅕ of the drift rate of a copper ion obtained in the conventional interlayer insulating film formed by using the divinylsiloxane bis-benzocyclobutene, it is understood that the second interlayer insulating film of Embodiment 2 has a better copper ion diffusion preventing function than the conventional interlayer insulating film. This seems to be because copper ions are efficiently trapped by the siloxane bonds dispersed in the network of the organic polymer as described above.

Moreover, the elasticity modulus of the second interlayer insulating film of Embodiment 2 measured with a nano indenter is approximately 8 GPa, which is equivalent to the elasticity modulus of the conventional interlayer insulating film made of an organic low dielectric constant film. Although the 1,3-diphenyl-1,1,3,3-tetramethyldisiloxane is used as the first CVD material in Embodiment 2, the three-dimensional network of the organic polymer can be definitely formed by using disiloxane having, as the organic groups bonded to silicon, three or more groups selected from the group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group. Thus, the elasticity modulus of the second interlayer insulating film can be further improved.

Alternatively, in Embodiment 2, a cyclic siloxane derivative in which any group selected from the group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group is bonded to a silicon atom can be used as the first CVD material instead of the organic disiloxane derivative. When such a cyclic siloxane compound is used as the first CVD material, the three-dimensional network of the organic polymer can be easily formed. As a result, the second interlayer insulating film with high mechanical strength can be definitely formed.

Furthermore, in Embodiment 2, an organic silicon compound in which at least two groups selected from the group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group are bonded to different silicon atoms can be used. Thus, the second interlayer insulating film having a structure in which siloxane bonds are separated from each other by an organic component without being adjacent to each other can be definitely formed.

Moreover, in Embodiment 2, when the deposition is performed through the plasma CVD in an atmosphere including a nitrogen gas or an ammonia gas, a bond of silicon and nitrogen (a Si-N bond) or a bond of carbon and nitrogen (a C-N bond) is formed in the deposited film, and therefore, the copper ion diffusion preventing function of the second interlayer insulating film can be improved.

### EMBODIMENT 3

An interlayer insulating film formation method according to Embodiment 3 of the invention for embodying the interlayer insulating film formation method (3) employing the plasma CVD of this invention will be described with reference to the accompanying drawings.

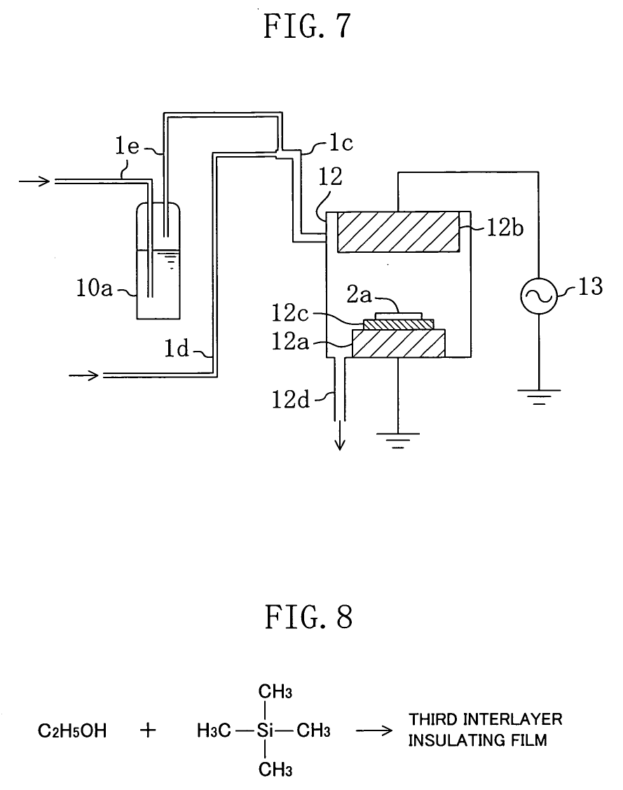

The interlayer insulating film formation method of Embodiment 3 is realized by using a general diode parallel plate cathode coupled plasma enhanced CVD system having an architecture, for example, schematically shown in FIG. 7.

Also, in the interlayer insulating film formation method of Embodiment 3, tetramethylsilane is used as a first CVD material, that is, the organic silicon compound including no oxygen atom, and ethanol is used as a second CVD material, that is, the organic compound including an oxygen atom, as shown in FIG. 8. A third interlayer insulating film according to this embodiment can be formed through plasma CVD using these first and second CVD materials. The method will now be specifically described.

First, tetramethylsilane used as the first CVD material is filled in a first pressure vessel 10a through a first gas supply pipe 1e, and the tetramethylsilane filled in the first pressure vessel 10a is introduced into a deposition chamber 12 through a third gas supply pipe 1c. On the other hand, ethanol is introduced into the deposition chamber 12 through a second gas supply pipe 1d and the third gas supply pipe 1c. In the deposition chamber 12, a lower electrode 12a is disposed on the bottom and an upper electrode 12b is disposed above the lower electrode 12a, and a target substrate 2a is placed on a substrate supporting portion 12c provided on the lower electrode 12a. Also, the deposition chamber 12 is provided with an outlet 12d on a side of the lower electrode 12a so that a gas obtained after a reaction or a gas having not sufficiently contributed to the reaction can be successively exhausted.

In Embodiment 3, with the pressure within the deposition chamber 12 set to 400Pa and the substrate temperature set to 400° C., while introducing the tetramethylsilane and the ethanol into the deposition chamber 12 at flow rates of 10 ccm and 5 cc/min., respectively, power of 0.2 W/cm² is applied to the lower electrode 12a and the upper electrode 12b by a radio frequency (RF) power source 13 for plasma polymerization. Owing to the plasma, the tetramethylsilane is partially oxidized by an oxygen radical, that is, a plasma decomposition component of methanol. Also, an organic component obtained by dissociating oxygen from the ethanol is copolymerized with the tetramethylsilane and a partial oxide of the tetramethylsilane. Thus, the third interlayer insulating film into which the organic component, a siloxane component and a bond of a silicon atom and a carbon atom (a Si-C bond) are introduced is formed.

Also, in Embodiment 3, when the third interlayer insulating film is formed by using the tetramethylsilane and the ethanol, the third interlayer insulating film can be obtained at a deposition rate of 200 nm/min., and its dielectric constant is 2.6. Since the dielectric constant of the conventional interlayer insulating film formed by using the divinylsiloxane bis-benzocyclobutene is 2.7, it is understood that the dielectric constant of the third interlayer insulating film of Embodiment 3 has a better value.

Furthermore, a drift rate of a copper ion obtained in the third interlayer insulating film under conditions of the applied electric field of 0.8 MV/cm and a temperature of 150° C. is 1.0×10⁵ ions/cm²s. Since this drift fate is approximately ⅕ of the drift rate of a copper ion obtained in the conventional interlayer insulating film formed by using the divinylsiloxane bis-benzocyclobutene, it is understood that the third interlayer insulating film of Embodiment 3 has a better copper ion diffusion preventing function than the conventional interlayer insulating film. This seems to be because copper ions are efficiently trapped by the siloxane bonds dispersed in the network of the organic polymer as described above.

Moreover, the elasticity modulus of the third interlayer insulating film of Embodiment 3 measured with a nano indenter is approximately 8 GPa, which is equivalent to the elasticity modulus of the conventional interlayer insulating film made of an organic low dielectric constant film. Although the tetramethylsilane is used as the first CVD material in Embodiment 3, the three-dimensional network of the organic polymer can be definitely formed by using disiloxane having, as the organic groups bonded to silicon, three or more groups selected from the group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group. Thus, the elasticity modulus of the third interlayer insulating film can be further improved.

Alternatively, propanol, butanol, dimethyl ether, diethyl ether, dipropyl ether, acetone, diethyl ketone, acetic acid, lactic acid or the like can be used as the organic compound including an oxygen atom instead of the ethanol. Also, the organic compound including an oxygen atom can be replaced with an organic substance including an oxygen atom.

Moreover, in Embodiment 3, when the deposition is performed through the plasma CVD in an atmosphere including a nitrogen gas or an ammonia gas, a bond of silicon and nitrogen (a Si-N bond) or a bond of carbon and nitrogen (a C-N bond) is formed in the deposited film, and therefore, the copper ion diffusion preventing function of the third interlayer insulating film can be improved.

In this manner, the present invention is useful for a method for forming an interlayer insulating film good at the copper ion diffusion preventing function, the thermal stability and the mechanical strength.

What is claimed is:

1. An interlayer insulating film formation method for forming an interlayer insulating film on a substrate comprising the step of:
forming said interlayer insulating film through plasma CVD by using an organic silicon compound including no oxygen atom and an organic silicon compound including an oxygen atom as materials.

2. The interlayer insulating film formation method of claim 1,
wherein a gas of nitrogen is used as an additive gas in the step of forming said interlayer insulating film.

3. The interlayer insulating film formation method of claim 1,
wherein a gas of ammonia is used as an additive gas in the step of forming said interlayer insulating film.

4. The interlayer insulating film formation method of claim 1,
wherein said organic silicon compound including no oxygen atom is monomethylsilane, dimethylsilane, trimethylsilane, tetramethylsilane or hexamethyldisilane.

5. The interlayer insulating film formation method of claim 1,
wherein an organic group bonded to a silicon atom included in said organic silicon compound including an oxygen atom is a methyl group, an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group or a derivative of a phenyl group.

6. An interlayer insulating film formation method for forming an interlayer insulating film on a substrate comprising the step of:
forming said interlayer insulating film through plasma CVD by using an organic compound including no oxygen atom and an organic silicon compound including an oxygen atom as materials.

7. The interlayer insulating film formation method of claim 6,
wherein a gas of nitrogen is used as an additive gas in the step of forming said interlayer insulating film.

8. The interlayer insulating film formation method of claim 6,
wherein a gas of ammonia is used as an additive gas in the step of forming said interlayer insulating film.

9. The interlayer insulating film formation method of claim 6,
wherein said organic compound including no oxygen atom is saturated carbon hydride or unsaturated carbon hydride.

10. The interlayer insulating film formation method of claim 9,
wherein said saturated carbon hydride is methane, ethane, propane, butane, pentane, hexane, heptane, octane, nonane, decane or an isomer of any of them.

11. The interlayer insulating film formation method of claim 9,
wherein said unsaturated carbon hydride includes one or more and three or less double bonds of carbon atoms.

12. The interlayer insulating film formation method of claim 6,
wherein an organic group bonded to a silicon atom included in said organic silicon compound including an oxygen atom is a methyl group, an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group or a derivative of a phenyl group.

13. An interlayer insulating film formation method for forming an interlayer insulating film on a substrate comprising the step of:
forming said interlayer insulating film through plasma CVD by using an organic silicon compound including no oxygen atom and an organic compound including an oxygen atom.

14. The interlayer insulating film formation method of claim 13,
wherein a gas of nitrogen is used as an additive gas in the step of forming said interlayer insulating film.

15. The interlayer insulating film formation method of claim 13,
wherein a gas of ammonia is used as an additive gas in the step of forming said interlayer insulating film.

16. The interlayer insulating film formation method of claim 13,
wherein said organic silicon compound including no oxygen atom is monomethylsilane, dimethylsilane, trimethylsilane, tetramethylsilane or hexamethyldisilane.

17. The interlayer insulating film formation method of claim 13,
wherein said organic compound including an oxygen atom is ether, ester, alcohol, ketone or a carboxylic acid derivative.

18. A film structure of an interlayer insulating film comprising an organic polymer including carbon atoms and hydrogen atoms as principal components,
wherein a first silicon atom bonded to a part said carbon atoms and not bonded to an oxygen atom and a second silicon atom bonded to a part of said carbon atoms and bonded to an oxygen atom are mixedly present in said organic polymer.

19. The film structure of an interlayer insulating film of claim 18,
wherein a ratio of the number of said carbon atoms to the number of said first silicon atom and said second silicon atom included in said interlayer insulating film is 1.5 or more.
